(19) United States
(12) Patent Application Publication
(10) Pub. No.: US 2003/0146483 A1
(43) Pub. Date: Aug. 7, 2003

(54) Metal pad of a semiconductor element

(75) Inventor: Ray Chien, Taipei (TW)

Correspondence Address: BRUCE H. TROXELL, SUITE 1404, 5205 LEESBURG PIKE, FALLS CHURCH, VA, 22041, US

(73) Assignee: VIA Technologies, Inc.

(21) Appl. No.: 10/342,098

(22) Filed: Jan. 15, 2003

(30) Foreign Application Priority Data
Feb. 1, 2002 (TW) 91101769

(51) Int. Cl. H01L 31/00

(52) U.S. Cl. 257/459

(57) ABSTRACT

A metal pad of a semiconductor element is disposed in an opening of a passivation layer of the semiconductor element and is connected to a metal interconnect layer of the semiconductor element through a plurality of metal plugs. The metal pad comprises a first aluminum alloy layer, a laser stop layer and a second aluminum alloy layer. The first aluminum alloy layer is disposed above the metal plugs; the laser stop layer is disposed on the upper surface of the first aluminum alloy layer and is made of a metal having a high melting point and a high laser reflection coefficient and has a thickness between 500 Å and 5000 Å; and the second aluminum alloy layer is disposed on the upper surface of the laser stop layer and has a thickness between 1000 Åand 20000 Å.

### FIELD OF THE INVENTION

The present invention relates to a metal pad of a semiconductor element and, more specifically, to a metal pad structure of a semiconductor element.

### BACKGROUND OF THE INVENTION

After the fabrication of an integrated circuit is finished, the integrated circuit chip is immovably bound and sealed using an electronic package technique so as to avoid destruction from an external force or other environmental factors. A package substrate is often used in the electronic package industry to affix the integrated circuit chip thereon, and it also provides one or more layers of metal interconnects, wherein one end of the metal interconnect is electrically connected to the integrated circuit chip, and the other end thereof is electrically connected to the other electronic modules (such as a motherboard, etc.). A plurality of metal pads are designed to be in the openings of the passivation layer (topmost layer) of the integrated circuit chip as a means to connect the metal interconnects of the package substrate to the integrated circuit chip.

Please refer to FIG. 1, which is a schematic diagram of the metal pad structure formed with AlCu (aluminum copper) alloy (or possibly AlSiCu (aluminum silicon copper alloy)) and its associated nearby structures in the prior art. The metal pad structure and its associated nearby structures include a first inter-metal dielectric layer 10, a first barrier metal layer 12, a metal layer 14, a thin anti-reflective coating layer 16, a second inter-metal dielectric layer 18, a plurality of metal plugs 20, a second barrier metal layer 22, a passivation layer 24 and a metal pad 26. Furthermore, a third, thin layer of barrier metal layer usually made of TiN (not explicitly drawn in FIG. 1) is on the sidewalls and bottom of the metal plugs 20.

The first inter-metal dielectric layer 10 is on a semiconductor substrate where transistors have been formed, and the first barrier metal layer 12 usually made of Ti, TiN or TaN is on the first inter-metal dielectric layer 10. The metal layer 14 is on the first barrier metal layer 12, and the thin anti-reflective coating layer 16 usually made of TiN, Ti/TiN or TaN is on the metal layer 14. The second inter-metal dielectric layer 18 is on the anti-reflective coating layer 16, and the passivation layer 24 is on the second inter-metal dielectric layer 18 and the metal pad 26. The passivation layer 24 has an opening 28 for baring the metal pad 26. The bottom of the metal pad 26 is connected with the second barrier metal layer 22, and the second barrier metal layer 22 usually made of Ti, TiN or TaN is connected with the metal plugs 20 which are in the second inter-metal dielectric layer 18 and extend downward to the anti-reflective coating layer 16. Hence, the transistors and passive elements of the integrated circuit electrically connected to the metal layer 14 can be electrically connected to the metal pad 26 through the metal plugs 20.

Referring to FIG.2, which is a schematic diagram of the metal pad structure formed by the copper metalization process and its associated nearby structures in the prior art. The metal pad structure and its associated nearby structures include a first inter-metal dielectric layer 30, a first barrier metal layer 32, a metal layer 34, a second inter-metal dielectric layer 38, a plurality of metal plugs 40, a second barrier metal layer 42, a passivation layer 44 and a metal pad 46.

The first inter-metal dielectric layer 30 is on a semiconductor substrate where transistors have been formed, and the first barrier metal layer 32 usually made of TaN is on the first inter-metal dielectric layer 30. The metal layer 34 is on the first barrier metal layer 32, and the second inter-metal dielectric layer 38 is on the metal layer 34, and the passivation layer 44 is on the second inter-metal dielectric layer 38 and the metal pad 46. The passivation layer 44 has an opening 48 for baring the metal pad 46. The bottom of the metal pad 46 is connected with the metal plugs 40. The metal pad 46 and the metal plugs 40 are a dual-damascene structure formed by the copper metalization process, and the sidewalls and bottom surfaces thereof are first covered by the second barrier metal layer 42 usually made of TaN. The metal plugs 40 are in the second inter-metal dielectric layer 38 and extend downward to the metal layer 34. Hence, the transistors and passive elements of the integrated circuit electrically connected to the metal layer 34 can be electrically connected to the metal pad 46 through the metal plugs 40.

Then, refer to FIG. 3, which is a schematic cross-sectional diagram of a bumpless flip-chip assembly process. Firstly, a package substrate 50 including a first surface 50a and a second surface 50b is provided, and then a layer of glue 52 is coated on the designated area of the first surface 50a of the package substrate 50 where a semiconductor element 54 is to beplaced upon. Subsequently, alignment and positioning using an optical camera are performed to affix the semiconductor element 54 on the area of glue 52 coated on the first surface 50a of the package substrate 50. The semiconductor element 54 has to be firmly pressed on the layer of glue 52 and a curing process is performed to have the layer of glue 52 completely solidified and cured. The semiconductor element 54 with a plurality of metal pads 56 (not explicitly drawn) is then bound on the layer of glue 52 of the first surface 50a of the package substrate 50. After an alignment procedure is performed to position each metal pad 56 of the semiconductor element 54, the package substrate 50 is then drilled from the second surface 50b thereof by using a laser drilling process to form a matching via hole 58 for each metal pad 56, and each via hole 58 is aligned with the matching metal pad 56. Via holes 58 and the surface 50b will then be deposited with metal layer, for the formation of electrical vias and interconnects (not explicit drawn in FIG. 3) thereafter.

Proper types of pulsed laser can be used in the laser drilling process, and the beam energy and duration cycle of laser pulses thereof are properly adjusted so as to fully penetrate the package substrate 50 and stop on the surface of the metal pad 56. FIG. 4 shows a schematic cross-sectional diagram illustrating a proper laser drilling process aiming on the metal pad structure of FIG. 1. In FIG. 4, multiple pulses of a laser beam 60 can fully penetrate the package substrate 50 and the layer of glue 52, and properly stop at the surface of the metal pad 26, or very gently penetrate into the surface of the metal pad 26.

However, because the fine controls for the lasing variables such as pulse duration fluctuation, power instability and drift of the laser beam 60 are limited, as well as the fine controls of the variations in thickness of the package substrate 50 and the layer of glue 52 are limited, plus the fact that the metal pad structure in prior arts cannot provide a built-in mechanism to have the laser beam to stop at an appropriate depth close to the surface of the metal pad 26, therefore it is very difficult for the laser beam to precisely stop at the appropriate depth close to the surface of the metal pad 26 each time during the laser drilling process. If the total energy of the laser beam 60 irradiated is insufficient or if the package substrate 50 is too thick, the laser beam 60 cannot penetrate through the package substrate 50. This will cause the semiconductor element 54 unable to electrically connect to the electrical vias and interconnects of the package substrate 50. On the other hand, if the total energy of the laser beam 60 irradiated is too high or if the package substrate 50 is too thin, the laser beam can penetrate the package substrate 50 and even penetrate the entire metal pad 26 onto the metal plugs 20 and causes damage to the pad and via structure. FIG. 5 is a schematic cross-sectional diagram illustrating an improper laser drilling process described hereinabove on the metal pad structure in FIG. 1. As illustrated in FIG. 5, the laser beam has penetrated into the metal plugs 20 and causes damage to the metal plugs 20 or other nearby elements.

Therefore, how to develop a novel metal pad of the semiconductor element and the process for manufacturing thereof so as to provide a mechanism to stop the laser beam at an appropriate depth close to the surface of the metal pad, has become an important subject for the semiconductor industry.

### SUMMARY OF THE INVENTION

The one objective of the present invention is to provide a metal pad of a semiconductor element.

Another objective of the present invention is to provide a metal pad structure of a semiconductor element, formed with AlCu (aluminum copper) alloy (or AlSiCu (aluminum silicon copper) alloy)

A further objective of the present invention is to provide a metal pad structure of a semiconductor element, formed by a copper metalization process.

An additional objective of the present invention is to provide a fabricating process for package modules of a semiconductor element.

In a first embodiment of this invention, a metal pad of a semiconductor element is disclosed, wherein the metal pad of the semiconductor element is disposed in an opening of a passivation layer of the semiconductor element and is connected to a metal interconnect layer of the semiconductor element through a plurality of metal plugs. The metal pad comprises a first aluminum alloy layer, a laser stop layer and a second aluminum alloy layer. The first aluminum alloy layer is disposed on the upper surface of the barrier metal on top of the metal plugs; the laser stop layer is disposed on the upper surface of the first aluminum alloy layer and is made of a metal having a high melting point and a high laser reflection coefficient and has a thickness between 500 Å and 5000 Å; and the second aluminum alloy layer is disposed on the upper surface of the laser stop layer and has a thickness between 1000 Å and 20000 Å.

In a second embodiment of the present invention, a metal pad of a semiconductor element disclosed is disposed in an opening of a passivation layer of the semiconductor element and is connected to a metal interconnect layer of the semiconductor element through a plurality of metal plugs. The metal pad comprises a first copper layer, a laser stop layer and a second copper layer. The first copper layer is disposed on the upper surface of the metal plugs, and the upper surface of the first copper layer is a curved surface. The laser stop layer is disposed on the upper surface of the first copper layer and is made of a metal having a high melting point and a high laser reflection coefficient and has a thickness between 500 Å and 5000 Å, and the upper and lower surfaces of the laser stop layer are curved surfaces. The second copper layer is disposed on the upper surface of the laser stop layer and has a thickness between 1000 Å and 20000 Å.

In a third embodiment of the present invention, a metal pad of a semiconductor element disclosed is disposed in an opening of a passivation layer of the semiconductor element and is connected to a metal interconnect layer of the semiconductor element through a plurality of metal plugs. The metal pad comprises a first copper layer and a laser stop layer. The first copper layer is disposed on the upper surface of the metal plugs, and the upper surface of the first copper layer is a curved surface. The laser stop layer is disposed on the upper surface of the first copper layer and is made of a metal having a high melting point and a high laser reflection coefficient and has a thickness between 500 Å and 10000 Å, and the lower surface of the laser stop layer is a curved surface.

### BRIEF DESCRIPTION OF THE DRAWINGS

The foregoing aspects and many of he attendant advantages of this invention will become more readily appreciated as the same becomes better understood by reference to the following detailed description, when taken in conjunction with the accompanying drawings, wherein:

FIG. 1 is a schematic diagram of a metal pad structure formed with AlCu (aluminum copper) alloy (or AlSiCu (aluminum silicon copper) alloy) and its associated nearby structures in the prior art;

FIG. 2 is a schematic diagram of a metal pad structure formed by the copper metalization process and its associated nearby structures in the prior art;

FIG. 3 is a schematic cross-sectional diagram of a bumpless flip-chip assembly process, wherein the metal pad is electrically connected to vias formed in the via holes and the via holes are formed by laser drilling.

FIG. 4 is a schematic cross-sectional diagram illustrating a proper laser drilling process on the metal pad structure of FIG. 1;

FIG. 5 is a schematic cross-sectional diagram illustrating an improper laser drilling process on the metal pad structure of FIG. 1;

FIG. 6 is a schematic diagram of a metal pad structure formed with AlCu (aluminum copper) alloy (or AlSiCu (aluminum silicon copper) alloy) and its associated nearby structures in a first embodiment of this invention;

FIG. 7 is a schematic diagram illustrating that the laser beam stops on or in the laser stop layer in the first embodiment of this invention;

FIG. 8 is a schematic diagram of a metal pad structure formed by the copper metalization process and its associated nearby structures in a second embodiment of this invention;

FIG. 9 is a schematic diagram illustrating that the laser beam stops on or in the laser stop layer in the second embodiment of this invention; and

FIG. 10 is a schematic diagram of a metal pad structure formed by the copper metalization process and its associated nearby structures in a third embodiment of this invention.

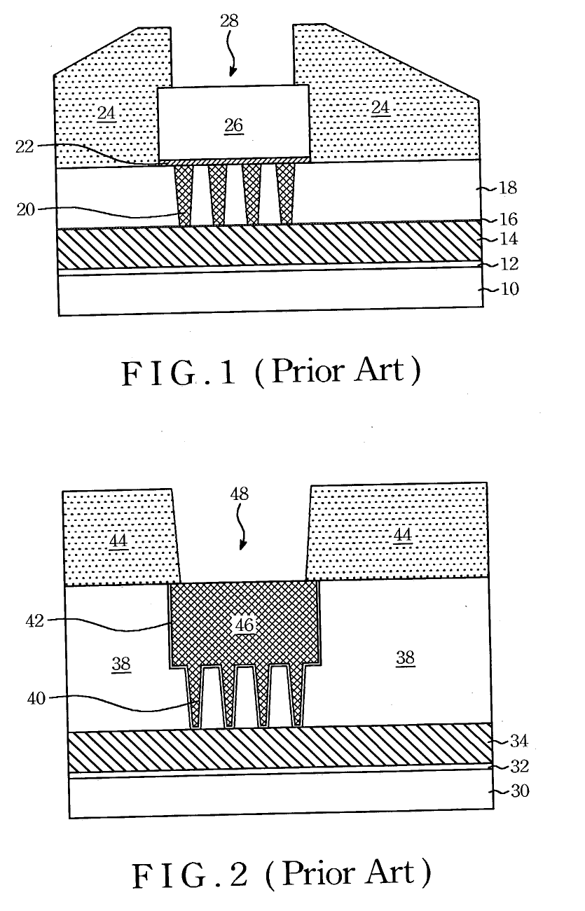

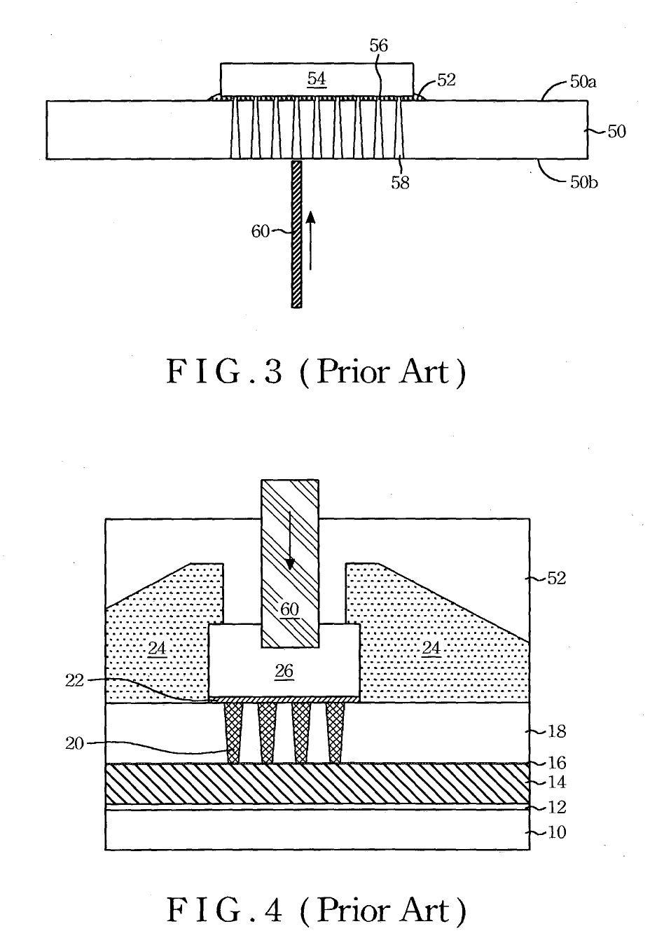

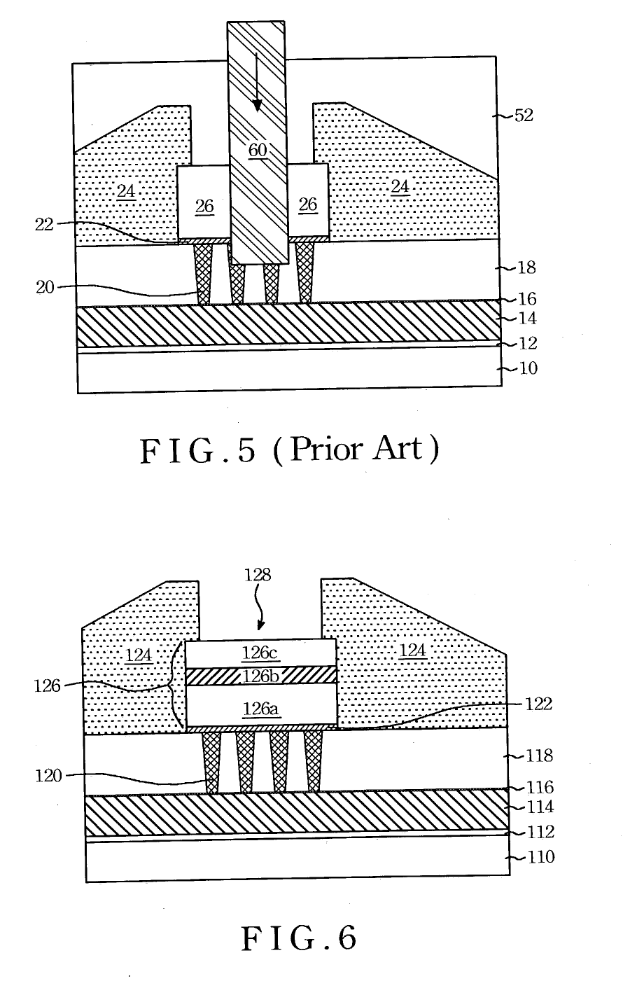

### DETAILED DESCRIPTION OF THE PREFERRED EMBODIMENTS

First, please refer to FIG. 6, which is a schematic diagram of a metal pad structure formed with AlCu (aluminum copper) alloy (or AlCu (aluminum silicon copper) alloy) and its associated nearby structures in a first embodiment of this invention. The metal pad structure and its associated nearby structures include a first inter-metal dielectric layer 110, a first barrier metal layer 112, a metal layer 114, an anti-reflective coating layer 116, a second inter-metal dielectric layer 118, a plurality of metal plugs 120, a second barrier metal layer 122, a passivation layer 124 and a tri-layer metal pad 126.

The first inter-metal dielectric layer 110 is a silicon dioxide layer on a semiconductor substrate where active elements and/or passive elements have been formed, and the first barrier metal-layer 112 made of Ti or TiN or TaN alloys is on the first inter-metal dielectric layer 110. The metal layer 114 made of aluminum copper alloy or aluminum silicon copper alloy is on the first barrier metal layer 112, and the anti-reflective coating layer 116 usually made of TiN, Ti/TiN or TaN is on the metal layer 114. The second inter-metal dielectric layer 118 is a silicon dioxide layer on the anti-reflective coating layer 116, and the passivation layer 124 is a multi-layer structure usually made of silicon dioxide, silicon nitride and/or silicon oxynitride, on top of the second inter-metal dielectric layer 118 and the metal pad 126.

The passivation layer 124 has an opening 128 for baring the metal pad 126. The bottom of the metal pad 126 is connected with the second barrier metal layer 122 usually made of Ti, TiN or TaN. The second barrier metal layer 122 is approximately on the same level as the bottom surface of the passivation layer 124, and is connected with a plurality of metal plugs 120 thereunder. The metal plugs 120 made of tungsten are in the second inter-metal dielectric layer 118 and extend downward to the anti-reflective coating layer 116. Hence, the active elements and/or passive elements of the integrated circuit electrically connected to the metal layer 114 can be electrically connected to the metal pad 126 through the metal plugs 120. Furthermore, a third, thin layer of barrier metal layer usually made of TiN (not explicitly drawn in FIG. 6) is on the sidewalls and bottom of the metal plugs 120.

The key of the first embodiment in this invention resides in that the metal pad 126 is a tri-layer structure constituted by a first aluminum alloy layer 126a, a second aluminum alloy layer 126c and a laser stop layer 126b, wherein the first aluminum alloy layer 126a made of AlCu (aluminum copper) alloy or AlSiCu (aluminum silicon copper) alloy is on the upper surface of the second barrier metal layer 122 and has a thickness between 2000 Å and 20000 Å; the laser stop layer 126b made of a metal having a high melting point and a high laser reflection coefficient, such as titanium (Ti), tungsten (W), TiW, tantalum (Ta), TaW or the alloys thereof, is on the upper surface of the first aluminum alloy layer 126a and has a thickness between 500 Å and 5000 Å; and the second aluminum alloy layer 126c also made of AlCu (aluminum copper) alloy or AlSiCu (aluminum silicon copper) alloy is on the upper surface of the laser stop layer 126b and has a thickness between 2000 Å and 20000 Å.

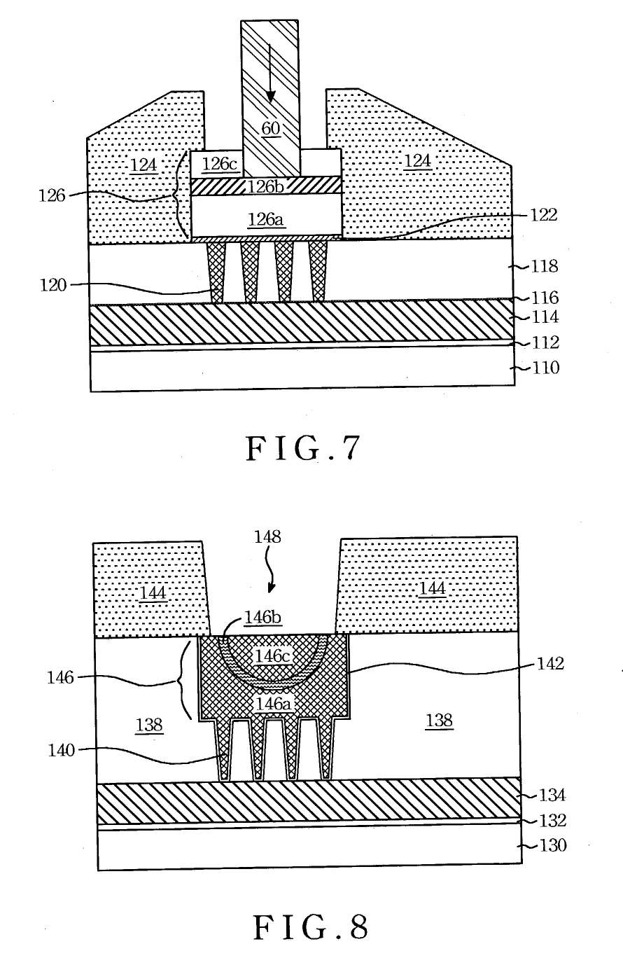

Since the laser stop layer 126b is made of a metal having a high melting point and a high laser reflection coefficient, it is not easy to be vaporized and removed by the laser beam. Hence, when the laser drilling process for the bumpless flip-chip assembly process is performed, the laser beam stops on or in the laser stop layer 126b, as shown in FIG. 7, even when the energy of the laser beam is slightly higher than normal or the package substrate is thinner than normal. Therefore, it enables to precisely control the laser drilling process for the bumpless flip-chip assembly process and the semiconductor element will not be damaged due to a higher than normal energy of the laser beam or the thinner thickness of the package substrate.

In addition, the laser stop layer 126b can also be a stress release layer for reducing the stress of the entire semiconductor substrate or semiconductor wafer.

Refer to FIG. 8, which is a schematic diagram of a metal pad structure formed by the copper metalization process and its associated nearby structures in a second embodiment of this invention. The metal pad structure and its associated nearby structures include a first inter-metal dielectric layer 130, a first barrier metal layer 132, a metal layer 134, a second inter-metal dielectric layer 138, a plurality of metal plugs 140, a second barrier metal layer 142, a passivation layer 144 and a metal pad 146.

The first inter-metal dielectric layer 130 is a silicon dioxide layer on a semiconductor substrate where transistors have been formed, and the first barrier metal layer 132 made of TaN alloys is on the first inter-metal dielectric layer 130. The metal layer 134 made of Cu (copper) is on the first barrier metal layer 132, and the second inter-metal dielectric layer 138 is a silicon dioxide layer on the metal layer 134. The passivation layer 144 is a multi-layer structure usually made of silicon dioxide, silicon nitride and/or silicon oxynitride, on the second inter-metal dielectric layer 138 and the metal pad 146.

The passivation layer 144 has an opening 148 for baring the metal pad 146. The bottom of the metal pad 146 is connected with the metal plugs 140. The metal pad 146 and the metal plugs 140 are a dual-damascene structure formed by the copper metalization process, and the sidewalls and bottom surfaces thereof are covered by the second barrier metal layer 142 usually made of TaN alloys. The metal plugs 140 are in the second inter-metal dielectric layer 138 and extend downward to the metal layer 134. Hence, the active and passive elements of the integrated circuit electrically connected to the metal layer 134 can be electrically connected to the metal pad 146 through the metal plugs 140.

The key of the second embodiment in this invention resides in that the metal pad 146 is a tri-layer structure constituted by a first copper layer 146a, a second copper layer 146c and a laser stop layer 146b, wherein the first copper layer 146a made of copper is on the upper surface of the second barrier metal layer 142 and has a thickness between 2000 Å and 20000 Å; the laser stop layer 146b made of a metal having a high melting point and a high laser reflection coefficient, such as titanium (Ti), tungsten (W), TiW, tantalum (Ta), TaW or the alloys thereof, is on the upper surface of the first copper layer 146a and has a thickness between 500 Å and 5000 Å; and the second copper layer 146c also made of copper is on the upper surface of the laser stop layer 146b and has a thickness between 2000Å and 20000 Å. In this embodiment, the upper surface of the first copper layer 146a, the upper/lower surfaces of the laser stop layer 146b and the lower surface of the second copper layer 146c are all curved surfaces which result from the process nature of the dual damascene copper metalization process.

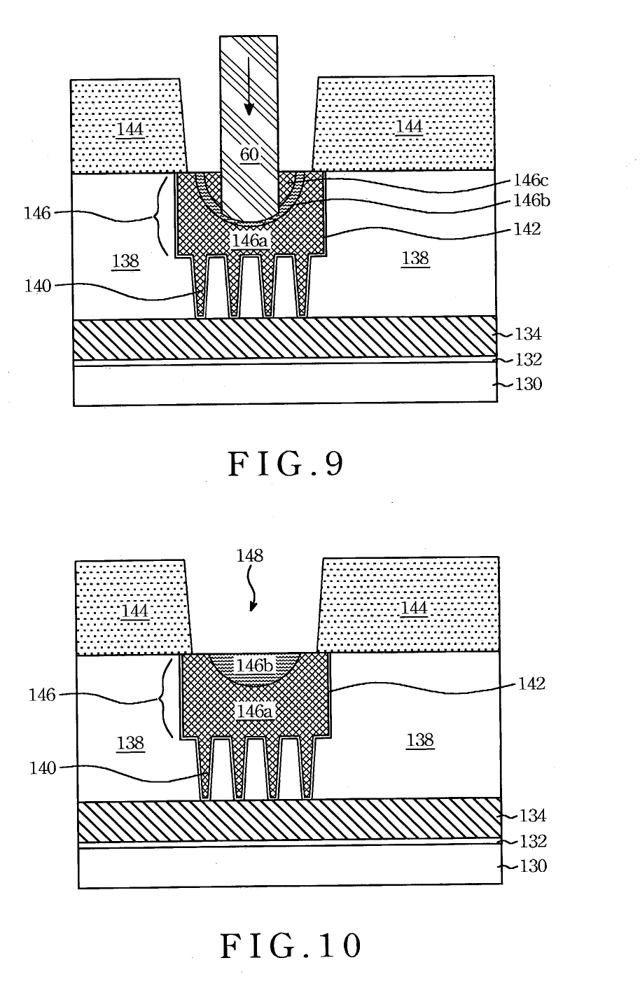

Since the laser stop layer 146b is made of a metal having a high melting point and a high laser reflection coefficient, it is not easy to be vaporized and removed by the laser beam. Hence, when the laser drilling process for the bumpless flip-chip assembly process is performed, the laser beam stops on or in the laser stop layer 146b, as shown in FIG. 9, even if the energy of the laser beam is slightly higher than normal or if the package substrate is thinner than normal. Therefore, it enables to precisely control the laser drilling process for the bumpless flip-chip assembly process and the semiconductor element will not be damaged due to a higher than normal energy of the laser beam or a thinner thickness of the package substrate.

In addition, the laser stop layer 146b can also be a stress release layer for reducing the stress of the entire semiconductor substrate or semiconductor wafer.

Further, refer to FIG. 10, which is a schematic diagram of a metal pad structure formed by the copper metalization process and its associated nearby structures in a third embodiment of this invention. The metal pad structure and its associated nearby structures include a first inter-metal dielectric layer 130, a first barrier metal layer 132, a metal layer 134, a second inter-metal dielectric layer 138, a plurality of metal plugs 140, a second barrier metal layer 142, a passivation layer 144 and a metal pad 146.

The first inter-metal dielectric layer 130 is a silicon dioxide layer on a semiconductor substrate where transistors have been formed, and the first barrier metal layer 132 made of TaN alloys is on the first inter-metal dielectric layer 130. The metal layer 134 made of Cu (copper) is on the first barrier metal layer 132, and the second inter-metal dielectric layer 138 is a silicon dioxide layer on the metal layer 134. The passivation layer 144 is a multi-layer structure usually made of silicon dioxide, silicon nitride and/or silicon oxynitride, on the second inter-metal dielectric layer 138 and the metal pad 146.

The passivation layer 144 has an opening 148 for baring the metal pad 146. The bottom of the metal pad 146 is connected with the metal plugs 140. The metal pad 146 and the metal plugs 140 are a dual-damascene structure formed by the copper metalization process, and the sidewalls and bottom surfaces thereof are covered by the second barrier metal layer 142 usually made of TaN alloys. The metal plugs 140 are in the second inter-metal dielectric layer 138 and extend downward to the metal layer 134. Hence, the active and passive elements of the integrated circuit electrically connected to the metal layer 134 can be electrically connected to the metal pad 146 through the metal plugs 140.

The key of the third embodiment in this invention resides in that the metal pad 146 is a double-layer structure constituted by a first copper layer 146a and a laser stop layer 146b, wherein the first copper layer 146a made of copper is on the upper surface of the second barrier metal layer 142 and has a thickness between 2000 Å and 40000 Å; and the laser stop layer 146b made of a metal having a high melting point and a high laser reflection coefficient, such as titanium (Ti), tungsten (W), TiW, tantalum (Ta), TaW or the alloys thereof, is on the upper surface of the first copper layer 146a and has a thickness between 500 Å and 10000 Å.

In this embodiment, the upper surface of the first copper layer 146a and the lower surface of the laser stop layer 146b are both curved surfaces which result from the process nature of thedual damascene copper metalization process.

Since the laser stop layer 146b is made of a metal having a high melting point and a high laser reflection coefficient, it is not easy to be vaporized and removed by the laser beam. Hence, when the laser drilling process for the bumpless flip-chip assembly process is performed, the laser beam stops on-or in the laser stop layer 146b, as shown in FIG. 9, even when the energy of the laser beam is slightly higher or the package substrate is thinner. Therefore, it enables to precisely control the laser drilling process for the bumpless flip-chip assembly process and the semiconductor element will not be damaged due to a higher than normal energy of the laser beam or a thinner thickness of the package substrate.

In addition, the laser stop layer 146b can also be a stress release layer for reducing the stress of the entire semiconductor substrate or semiconductor wafer.

As is understood by a person skilled in the art, the foregoing preferred embodiments of the present invention are illustrative of the present invention rather than limiting of the present invention. It is intended to cover various modifications and similar arrangements included within the spirit and scope of the appended claims, the scope of which should be accorded the broadest interpretation so as to encompass all such modifications and similar structure.

What is claimed:

1. A metal pad of a semiconductor element, disposed in an opening of a passivation layer of said semiconductor element, and connected to a metal interconnect layer of said semiconductor element through a plurality of metal plugs; said metal pad comprising:
a first aluminum alloy layer, disposed above said metal plugs;
a laser stop layer, disposed on the upper surface of said first aluminum alloy layer, made of a metal having a high melting point and a high laser reflection coefficient, and having a thickness between 500 Å and 5000 Å; and
a second aluminum alloy layer, disposed on the upper surface of said laser stop layer and having a thickness between 1000 Å and 20000 Å.

2. The metal pad of claim 1, wherein said laser stop layer is made of titanium (Ti).

3. The metal pad of claim 1, wherein said laser stop layer is made of tungsten (W).

4. The metal pad of claim 1, wherein said laser stop layer is made of TiW alloy.

5. The metal pad of claim 1, wherein said laser stop layer is made of tantalum (Ta).

6. The metal pad of claim 1, wherein said laser stop layer is made of TaW.

7. The metal pad of claim 1, wherein said laser stop layer is made of titanium (Ti), tungsten (W), TiW, tantalum (Ta), TaW or any combination of the alloys thereof.

8. A metal pad of a semiconductor element, disposed in an opening of a passivation layer of said semiconductor element, and connected to a metal interconnect layer of said semiconductor element through a plurality of metal plugs; said metal pad comprising:
a first copper layer, disposed on the upper surface of said metal plugs, wherein the upper surface of said first copper layer is a curved surface;
a laser stop layer, disposed on the upper surface of said first copper layer, made of a metal having a high melting point and a high laser reflection coefficient, and having a thickness between 500 Å and 5000 Å, wherein the upper and lower surfaces of said first copper layer are curved surfaces; and
a second copper layer, disposed on the upper surface of said laser stop layer and having a thickness between 1000 Å and 20000 Å, wherein the lower surface of said second copper layer is a curve surface.

9. The metal pad of claim 8, wherein said laser stop layer is made of titanium (Ti).

10. The metal pad of claim 8, wherein said laser stop layer is made of tungsten (W).

11. The metal pad of claim 8, wherein said laser stop layer is made of TiW alloy.

12. The metal pad of claim 8, wherein said laser stop layer is made of tantalum (Ta).

13. The metal pad of claim 8, wherein said laser stop layer is made of TaW alloy.

14. The metal pad of claim 8, wherein said laser stop layer is made of titanium (Ti), tungsten (W), TiW, tantalum (Ta), TaW or any combination of the alloys thereof.

15. A metal pad of a semiconductor element, disposed in an opening of a passivation layer of said semiconductor element, and connected to a metal interconnect layer of said semiconductor element through a plurality of metal plugs; said metal pad comprising:
a first copper layer, disposed on the upper surface of said metal plugs, wherein the upper surface of said first copper layer is a curved surface; and
a laser stop layer, disposed on the upper surface of said first copper layer, made of a metal having a high melting point and a high laser reflection coefficient, and having a thickness between 500 Å and 10000 Å, wherein the lower surface of said first copper layer is a curved surface.

16. The metal pad of claim 15, wherein said laser stop layer is made of titanium (Ti).

17. The metal pad of claim 15, wherein said laser stop layer is made of tungsten (W).

18. The metal pad of claim 15, wherein said laser stop layer is made of TiW alloy.

19. The metal pad of claim 15, wherein said laser stop layer is made of tantalum (Ta).

20. The metal pad of claim 15, wherein said laser stop layer is made of TaW alloy.
